(19) United States
(12) Patent Application Publication
(10) Pub. No.: US 2025/0157366 A1
(43) Pub. Date: May 15, 2025

(54) LIMIT DISPLAY DEVICE

(71) Applicant: Accelink Technologies Co., Ltd., Wuhan, Hubei (CN)

(72) Inventors: Weilin GUAN, Wuhan, Hubei (CN); Jiekui YU, Wuhan, Hubei (CN); Qin WANG, Wuhan, Hubei (CN); Guoliang HE, Wuhan, Hubei (CN); Feng XIA, Wuhan, Hubei (CN); Wenquan LEI, Wuhan, Hubei (CN); Qing LUO, Wuhan, Hubei (CN); Benqing QUAN, Wuhan, Hubei (CN)

(73) Assignee: Accelink Technologies Co., Ltd., Wuhan, Hubei (CN)

(21) Appl. No.: 18/838,471

(22) PCT Filed: Jun. 24, 2022
(86) PCT No.: PCT/CN2022/101158

§ 371 Date: Aug. 14, 2024

(30) Foreign Application Priority Data
Feb. 15, 2022 (CN) 202210137569.7

(51) Int. Cl. G09F 9/37; H05K 7/14

(52) U.S. Cl. CPC G09F 9/37; H05K 7/1401; H05K 2201/10128

(57) ABSTRACT

Disclosed is a limit display device comprising a movable assembly, limit assembly and display assembly. The display assembly is fixed in the movable assembly. The movable assembly is slidably matched with the limit assembly and comprises a limit slot. The limit assembly comprises a limit rod, one end of which is embedded into the limit slot, and the other end of which is fixed to the limit assembly; when the movable assembly drives the display assembly to slide, the limit rod synchronously slides along a preset path of the limit slot, keeping a locked or unlocked state of the display device. The limit display device is set on a side close to an inwall of a case and uses a hidden drawing mode, whereby a display screen of the display device may be completely exposed or hidden, avoiding touching the display screen mistakenly, and reducing the occupation of the space of the case in depth direction.

### INFORMATION ON RELATED APPLICATIONS

The present disclosure claims the priority of China patent application with the application number of 202210137569.7 filed to China National Intellectual Property Administration on Feb. 15, 2022, titled “LIMIT DISPLAY DEVICE”, the disclosure of which is hereby incorporated by reference herein in its entirety.

### TECHNICAL FIELD OF THE DISCLOSURE

The present disclosure belongs to the technical field of communication equipment, and in particular, relates to a limit display device.

### BACKGROUND

In the process of continuous evolution of communication products, the space capacity having the same size will be required to bear more and more data exchange capacity, the packaging volume of the optical module will be continuously miniaturized, and the transmission rate will be continuously improved. Meanwhile, all kinds of interaction information between products and operators is also indispensable, such as indicating lights, silk screen logos, company logos, board card slot numbers, version of the host frame, IP, and other information, which needs to be carried in a certain space. The interaction information is generally set on the front of the product for easy identification, but the occupied space will significantly affect the integration level of the product, thus reducing the number of optical modules in the product and changing the layout of the optical modules.

In the currently existing technical solutions, there are several following solutions in order to solve the relationship between the display content and the occupation of the space of the panel: solution I, using the liquid crystal display with the width as small as possible, arranging it on the front panel of the product, and reducing the occupied effective space as much as possible; solution II, printing some static information on the label by using a mode of fixing the thin label, and sticking it on the top surface, the side face or the structural member of various handles of the product; solution III, setting the display screen on the hangers on both sides of the installation equipment, and using the space for installing the hangers to set the display device. Through the comprehensive analysis to the above solutions, they each have defects in different degrees. In solution I, the width of the display screen will reach a limit if it is small to a certain extent, and the width of 15 mm will become a bottleneck in consideration of the space required for installation, and then it will be very difficult to further reduce it. In solution II, the label in a sticking mode is used, which can only bear some static information of the product but cannot bear the dynamic information of the product in real time. In solution III, the display screen is set at the installation position of the hanger, which increases the processing difficulty of the product, brings inconvenience to the on-site installation, and has the risk of failure due to installation problems.

In view of the above, overcoming the defects existing in the prior art is an urgent problem to be solved in this technical field.

### SUMMARY

Aiming at the above-mentioned defects or improvement requirements of the prior art, the present disclosure provides a limit display device, which aims to solve the technical problem that the occupied space of the case panel is large and the dynamic information of the product cannot be displayed at the same time through setting the display device in the case as well as using a hidden drawing mode.

In order to realize the above-mentioned purpose, according to one aspect of the present disclosure, there is provided a limit display device which comprises a movable assembly, a limit assembly and a display assembly,
wherein the display assembly is fixed in the movable assembly, and the movable assembly is slidably matched with the limit assembly;
wherein the movable assembly comprises a limit slot, and the limit assembly comprises a limit rod, one end of which is embedded into the limit slot, and the other end of which is fixed to the limit assembly; and
wherein the limit rod synchronously slides along a path preset by the limit slot when the movable assembly drives the display assembly to slide, so as to keep a locked state or an unlocked state of the display device.

As a further improvement and supplement to the above-mentioned solution, the present disclosure further comprises the following additional technical features.

In one example, the limit slot comprises a first groove, a second groove and a third groove, wherein
two ends of the third groove are respectively connected with the first groove and the second groove, and one end of the third groove is connected with a preset position in the middle of the first groove;
when the third groove is connected with the second groove, an end face of the third groove is lower than an end face of the second groove;
when the third groove is connected with the first groove, the end face of the third groove is higher than an end face of the first groove;
the limit rod is embedded into the second groove after ascending along the first groove from an end point of one end of the first groove which is not connected with the second groove, and the movable assembly is in a locked state;
the limit rod falls into the third groove along the second groove, and falls into the middle of the first groove after ascending along the third groove and slides to the end point of one end of the first groove which is not connected with the second groove, and the movable assembly completes a reset.

In one example, the second groove comprises a first edgefold, a second edgefold, a third edgefold, a fourth edgefold and a fifth edgefold, wherein
the first edgefold, the second edgefold and the third edgefold on one hand, and the fourth edgefold and the fifth edgefold on the other hand are located on two sides of the second groove, respectively;
the second edgefold forms a first concave point and a first convex point with the first edgefold (fold edge) and the third edgefold, respectively, and the fourth edgefold and the fifth edgefold form a second concave point;
the limit rod slides into the second concave point along the first concave point and the first convex point, and the limit rod is in a locked state;
if the limit rod slides into the third groove along the fourth edgefold in the second concave point, the limit rod is unlocked.

In one example, the movable assembly comprises a bottom plate and a panel, wherein the bottom plate is set with an area for accommodating the display assembly, and the panel is set with a window, the display assembly being fixed between the bottom plate and the panel, and the window being used for displaying display content and/or being electrically connected with an outside.

In one example, the limit assembly further comprises a first limit member and a second limit member, wherein
the first limit member and the second limit member respectively sleeve the bottom plate and the panel of the movable assembly, and a central axis of the first limit member and a central axis of the second limit member are located on a same connecting line;
the first limit member and the second limit member are respectively fixed to an inwall (inner wall) of a case;
the movable assembly slides in a space formed by the first limit member, the second limit member and the inwall of the case.

In one example, the limit assembly further comprises an elastic member, one end of which is fixed to a fixing column set on the bottom plate, and the other end of which is fixed to an inside of the case, the elastic member is kept in a stretched state, and when the limit rod is in a locked state, the elastic member is capable of driving the limit slot to slide so that the limit rod is unlocked.

In one example, the first limit member comprises a first flange, a second flange and a guidepost,
wherein the first flange and the second flange are respectively set on two sides of the first limit member; and meanwhile, the first flange and the second flange respectively sleeve the bottom plate, and the first flange and the second flange are respectively fixed to the inwall of the case;
the bottom plate and the panel are set with a guide sliding groove at the same position, which penetrates through the bottom plate and the panel, and into which the guidepost is embedded, and when the bottom plate and the panel slide, the guidepost is driven to synchronously slide along the guide sliding groove.

In one example, the display assembly comprises a soft belt and a display screen, both of which are electrically connected with each other, a surface of the bottom plate is set with a concave groove, and after the soft belt and the display screen are embedded into the concave groove, the soft belt and the display screen are in the same plane as the bottom plate.

In one example, a soft belt reinforcement film is stuck on a back surface of the soft belt for enhancing a hardness of the soft belt, and a PC film is selected as the soft belt reinforcement film.

In one example, the device further comprises a guide plate which is fixed to the inwall of the case, and the soft belt is accommodated in a gap between the guide plate and the inwall of the case, the soft belt being electrically connected with a back plate of the case, and the guide plate being convenient for the soft belt to extend and contract.

In general, compared with the prior art, the above technical solutions conceived by the present disclosure has the following beneficial effects:

According to the limit display device provided by the present disclosure, the limit display device is set on a side close to the inwall of the case and uses a hidden drawing mode; and the display device can be drawn just if a handle is exposed. When drawn once, the display screen of the display device can be completely exposed out of the case; and when drawn twice, the display screen of the display device is retracted back into the case. As a result, touching on the display screen by mistake may be avoided, and meanwhile, the occupation of the space of the case in the depth direction is reduced.

In the present disclosure, the limit of the width and the space occupied by the display screen and installation can be broken through, and the valuable space of the panel occupied by the width of the display screen is practically reduced, and further not only the static information of the product can be displayed, the dynamic information can also be displayed, which is simple to operate and easy to read data.

### BRIEF DESCRIPTION OF THE DRAWINGS

In order to more clearly explain the embodiments of the present disclosure or the technical solutions in the prior art, the drawings required in the embodiments or the description of the prior art are briefly introduced in the followings; obviously, the drawings in the following description are some embodiments of the present disclosure, and for those skilled in the art, and other drawings may be obtained according to these drawings without any inventive labor.

FIG. 1 is a schematic diagram of a limit display device provided in the present embodiment I.

FIG. 2 is a schematic diagram of a limit display device provided in the present embodiment I.

FIG. 3 is a schematic diagram of a limit slot in a limit display device provided in the present embodiment I.

FIG. 4 is a schematic diagram of a panel in a limit display device provided in the present embodiment I.

FIG. 5 is a schematic diagram of a bottom plate in a limit display device provided in the present embodiment I.

FIG. 6 is a schematic diagram of a combination of a bottom plate and a display assembly in a limit display device provided in the present embodiment I.

FIG. 7 is a schematic diagram of a guide plate in a limit display device provided in the present embodiment I.

In all figures, the same reference signs are used to represent the same elements or structures, wherein
1—movable assembly
11—limit slot
111—first groove
112—second groove
1121—first edgefold
114—second edgefold
1122—third edgefold
1124—fourth edgefold
1125—fifth edgefold
1126—first concave point
1127—first convex point
1128—second concave point
1129—second convex point
113—third groove
12—bottom plate
121—fixing column
122—concave groove
13—panel
131—window
132—key
14—guide sliding groove
2—limit assembly
21—limit rod
22—first limit member
221—first flange
222—second flange
223—guidepost
23—second limit member
24—elastic member
3—display assembly
31—soft belt
32—display screen
4—guide plate

### DETAILED DESCRIPTION

In order to make the objectives, technical solutions and advantages of the present disclosure clearer, the present disclosure will be further described in detail below with reference to the drawings and embodiments. It should be understood that the specific embodiments described herein are only used to explain the present disclosure and are not intended to limit the present disclosure. In addition, the technical features involved in various embodiments of the present disclosure described below can be combined with each other as long as they do not conflict with each other.

In the description of the present disclosure, the orientation or position relationship indicated by the terms “inner”, “outer”, “longitudinal”, “lateral”, “upper”, “lower”, “top”, “bottom” and the like is based on the orientation or positional relationship shown in the drawings, which is only for the purpose of describing the present disclosure rather than requiring the present disclosure must be constructed and operated in a specific orientation, and therefore should not be understood as a limitation to the present disclosure.

In the present disclosure, unless otherwise definitely specified and limited, that the first feature is “above” or “below” the second feature may include that the first feature and the second feature are directly in contact with each other, or may also include that the first feature and the second feature are in contact through another feature between the first feature and the second feature rather than being directly in contact with each other. Moreover, the words “above”, “over” and “on” the first feature include that the first feature is right above and obliquely above the second feature, or merely indicate that the horizontal height of the first feature is higher than that of the second feature. The words “under”, “below” and “low” of the first feature include that the first feature is right below and obliquely below the second feature, or only merely indicate that the horizontal height of the first feature is less than that of the second feature.

### Embodiment I

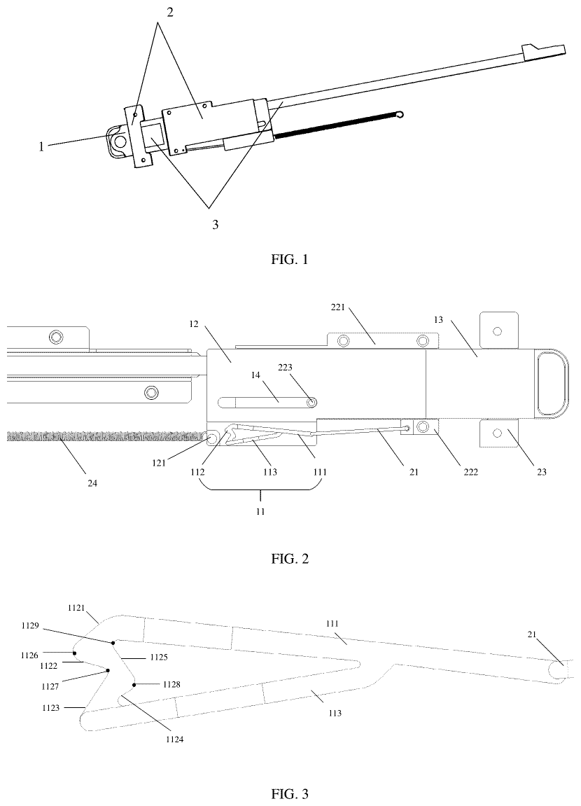

The present embodiment I provides a limit display device, and as shown in FIG. 1 and FIG. 2, the device comprises a movable assembly 1, a limit assembly 2 and a display assembly 3, wherein the display assembly 3 is fixed in the movable assembly 1, and the movable assembly 1 is slidably matched with the limit assembly 2.

A bottom plate 12 of the movable assembly 1 is set with a guide sliding groove 14. A first limit member 22 of the limit assembly 2 is set with a guidepost 223. The guidepost 223 is embedded into the guide sliding groove 14 and slides along the guide sliding groove 14. Meanwhile, a panel 13 of the movable assembly 1 is sleeved with a second limit member 23 of the limit assembly 2, the bottom plate 12 of the movable assembly 1 is sleeved with the first limit member 22, and the movable assembly 1 moves in a space between the limit assembly 2 and an inwall of a case.

The movable assembly 1 comprises a limit slot 11. The limit assembly 2 comprises a limit rod 21. One end of the limit rod 21 is embedded into the limit slot 11, and the other end of the limit rod 21 is fixed to the limit assembly 2.

The limit slot 11 is set on a back surface of the bottom plate 12 of the movable assembly 1, and the limit slot 11 is fit to the inwall of the case. The free end of the limit rod 21 is embedded into the limit slot 11 of the movable assembly 1, and the fixed end of the limit rod 21 is connected with a second flange 222 of the limit assembly 2.

When the movable assembly 1 drives the display assembly 3 to slide, the limit rod 21 synchronously slides along a path preset by the limit slot 11, so as to keep a locked state or an unlocked state of the display device.

The display device is set on a side close to the inwall of the case and uses a hidden drawing mode, and the display device can be drawn if a handle is exposed once. When the display device is drawn once, the display assembly 3 of the display device can be completely exposed out of the case, and when drawn twice, the display assembly 3 of the display device is retracted back into the case, thereby achieving the effect of reducing the occupation of the panel of the case. In the embodiment I, the limit of the width and the space occupied by the display screen and installation can be broken through, and the valuable space of the panel occupied by the width of the display screen is practically reduced. Moreover, the display screen in the display assembly 3 not only may display the static information of the product, but also may display dynamic information, which is simple to operate and easy to read data.

In the embodiment I, in order to meet that the limit rod 21 is locked in the limit slot 11 and unlocked from the limit slot 11, there is also a preferred implementation in combination with the embodiment of the present disclosure. Specifically, as shown in FIG. 2, the limit slot 11 comprises a first groove 111, a second groove 112 and a third groove 113, wherein two ends of the third groove 113 are respectively connected with the first groove 111 and the second groove 112, and one end of the third groove 113 is connected with a preset position in the middle of the first groove 111.

The preset position is between one third and one half of the first groove 111. It is selected to be located at one-third in the present embodiment I, and a chamfer is set at the connection between the third groove 113 and the middle of the first groove 111.

In order to reduce the resistance of the limit rod 21 when sliding from the second groove 112 to the third groove 113, when the third groove 113 is connected with the second groove 112, an end face of the third groove 113 is lower than an end face of the second groove 112.

In order to prevent the limit rod 21 from falling into the third groove 113 when sliding from the first groove 111 to the second groove 112, when the third groove 113 is connected with the first groove 111, an end face of the third groove 113 is higher than an end face of the first groove 111.

The limit rod 21 is embedded into the second groove 112 after ascending along the first groove 111 from an end point of one end of the first groove 111 which is not connected with the second groove 112, and the movable assembly 1 is in a locked state. The first groove 111 is set with a slope surface near the second groove 112.

The limit rod 21 is embedded into the second groove 112 after ascending along the first groove 111 from the end point of one end of the first groove 111 which is not connected with the second groove 112, and the movable assembly 1 is in a locked state. After the limit rod 21 is embedded into the limit slot 11, it is set as a starting position where the limit rod 21 locates when it is at the end point of one end of the first groove 111 which is not connected with the second groove 112. After the panel 13 of the movable assembly 1 is drawn once at the starting position, the limit rod 21 is slidably embedded into the second groove 112 from the first groove 111, and the limit rod 21 is locked in the second groove 112.

The limit rod 21 falls into the third groove 113 along the second groove 112, and falls into the middle of the first groove 111 after ascending along the third groove 113 and then slides to the end point of one end of the first groove 111 which is not connected with the second groove 112, then the movable assembly 1 completes the reset. After the limit rod 21 is in the locked state, the panel 13 of the movable assembly 1 is drawn twice, and under the action of the reverse drawing of the elastic member 24, the limit rod 21 falls into the third groove 113 along the second groove 112, and falls into the middle of the first groove 111 after ascending along the third groove 113 and then slides to the starting position, then the limit rod 21 is released from the locked state. The third groove 113 is set with a slope surface at the middle.

In the embodiment I, in order to meet that the limit rod 21 switches between the locked state and the unlocked state within the second groove 112, there is also a preferred implementation in combination with the embodiment of the present disclosure. Specifically, as shown in FIG. 2 and FIG. 3, the second groove 112 comprises a first edgefold 1121, a second edgefold 114, a third edgefold 1122, a fourth edgefold 1124 and a fifth edgefold 1125, wherein the first edgefold 1121, the second edgefold 114 and the third edgefold 1122 on one hand, and the fourth edgefold 1124 and the fifth edgefold 1125 on the other hand are located on two sides of the second groove 112, respectively.

The second edgefold 114 forms a first concave point 1126 and a first convex point 1127 with the first edgefold 1121 and the third edgefold 1122, respectively, and the fourth edgefold 1124 and the fifth edgefold 1125 form a second concave point 1128.

The limit rod 21 slides into the second concave point 1128 along the first concave point 1126 and the first convex point 1127, and the limit rod 21 is in a locked state.

As shown in FIG. 3, the first edgefold 1121, the second edgefold 114, and the third edgefold 1122 are located on a left side of the second groove 112, and a fourth edgefold 1124 and a fifth edgefold 1125 are located on a right side of the second groove 113.

The position where the limit rod 21 locates when it is at the end point of one end of the first groove 111 which is not connected with the second groove 112 is set as a starting position, and when the limit rod 21 is at the starting position, the movable assembly 1 is drawn rightwards once, then the limit slot 11 is synchronously drawn rightwards, and the limit rod 21 firstly slides into the first concave point 1126 along the first edgefold 1121 on the left side of the second groove 112, the limit slot 11 stops sliding under the drawing action outside of the case. At this moment, if the movable assembly 1 is stopped drawing, the limit slot 11 slides leftwards under the stretching action of the elastic member 24, and thus the limit rod 21 slides out of the first concave point 1126. After passing through the first convex point 1127, the limit rod 21 falls into the second concave point 1128, and at this moment, the elastic member 24 could not draw the limit slot 11 leftwards again, and the limit rod 21 and the movable assembly 1 are in the locked state.

If the limit rod 21 slides into the third groove 113 along the fourth edgefold 1124 in the second concave point 1128, the limit rod 21 is unlocked.

As shown in FIG. 3, the limit rod 21 falls into the second concave point 1128, and after the limit rod 21 and the movable assembly 1 are in the locked state, the movable assembly 1 is drawn rightwards secondly on the outside of the case, the limit slot 11 slides rightwards, and the limit rod 21 slides downwards from the second concave point 1128 and falls into the third groove 113.

In order to avoid the limit rod 21 directly falling into the third groove 113 along the first edgefold 1121, a second convex point 1129 is formed at the intersection of the fifth edgefold 1125 and the first groove 111, and the convex point of the second convex point 1129 faces a direction perpendicular to the first edgefold 1121.

In order to avoid the limit rod 21 directly falling into the third groove 113 along the second edgefold 114, the second edgefold 114 is inclined towards the third groove 113, and the convex point of the first convex point 1127 faces a direction perpendicular to the fifth edgefold 1125.

A chamfer is set at the connection of the fourth edgefold 1124 and the third groove 113, and thus the process that the limit rod 21 falls into the third groove 113 from the second groove 112 will be smoother, and the resistance in the process of groove changing will be reduced.

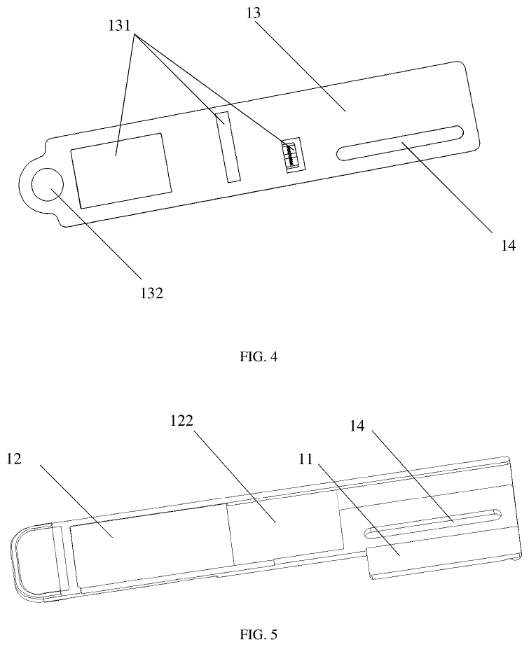

In order to embed the display assembly 3 into the movable assembly 1 and to drive the display assembly 3 to be exposed out of the case or hidden into the case when the movable assembly 1 is drawn, there is also a preferred implementation in combination with the embodiment of the present disclosure. Specifically, as shown in FIG. 4 and FIG. 5, the movable assembly 1 comprises a bottom plate 12 and a panel 13, wherein the bottom plate 12 is set with an area for accommodating the display assembly 3, and the panel 13 is set with a window 131, the display assembly 3 being fixed between the bottom plate 12 and the panel 13, and the window 131 being used for displaying the display content and/or being electrically connected with the outside.

As shown in FIG. 6, a concave groove 122 is set on a surface of the bottom plate 12, and after the soft belt 31 and the display screen 32 are embedded into the concave groove 122, the soft belt 31 and the display screen 32 are in the same plane as the bottom plate 12. The window 131 may display the display content of the display screen 32, and may also be electrically connected with the soft belt through the window 131.

As shown in FIG. 4, the panel 13 is further set with a key 132. Considering that the information capacity displayed by the display screen 32 is limited, the panel 13 can be electrically connected with the bottom plate 12 through the set panel 13, and by pressing the key 132 to complete the screen scrolling function of the display screen 32, the multi-screen display is realized, which may significantly improve the information capacity of the display screen 32. A handle end of the bottom plate 12 is fit to the key 132 of the panel 13, which is convenient for pressing the key 132 and drawing the bottom plate 12.

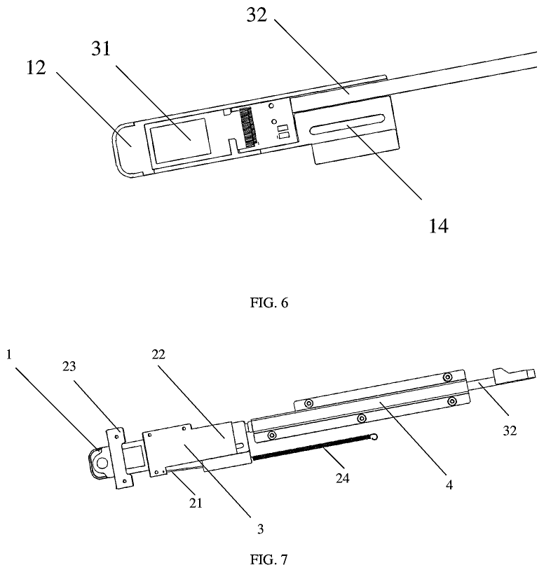

In the embodiment I, in order to limit the active area of the bottom plate 12 and the panel 13 respectively, there is also a preferred implementation in combination with the embodiment of the present disclosure. Specifically, as shown in FIG. 7, the limit assembly 2 further comprises a first limit member 22 and a second limit member 23, wherein the first limit member 22 and the second limit member 23 respectively sleeves the bottom plate 12 and the panel 13 of the movable assembly 1, and the central axes of the first limit member 22 and of the second limit member 23 are located on the same connecting line;
wherein the first limit member 22 and the second limit member 23 are respectively fixed to the inwall of the case; and
wherein the movable assembly 1 slides in a space formed by the first limit member 22, the second limit member 23 and the inwall of the case.

In the embodiment I, in order to limit the sliding stroke of the bottom plate 12, there is also a preferred implementation in combination with the embodiment of the present disclosure. Specifically, as shown in FIG. 2, the first limit member 22 comprises a first flange 221, a second flange 222 and a guidepost 223, wherein the first flange 221 and the second flange 222 are respectively set on two sides of the first limit member 22, and meanwhile, the first flange 221 and the second flange 222 sleeve the bottom plate 12, and both are respectively fixed to the inwall of the case; and
the bottom plate 12 and the panel 13 are set with a guide sliding groove 14 at the same position, the guide sliding groove 14 penetrating through the bottom plate 12 and the panel 13, and the guidepost 223 is embedded into the guide sliding groove 14 and when the bottom plate 12 and the panel 13 slide, is driven to synchronously slide along the guide sliding groove 14.

When the fixed end of the limit rod 21 is located at the second flange 222, and the free end of the limit rod 21 is located at the end point of one end of the first groove 111 which is not connected with the second groove 112, the two ends of the fixing column 122 and the limit rod 21 are in the same straight line.

In the embodiment I, in order to fix the display assembly 3 and reduce the occupation in space, there is also a preferred implementation in combination with the embodiment of the present disclosure. Specifically, as shown in FIG. 6, the display assembly 3 comprises a soft belt 31 and a display screen 32, and the soft belt 31 is electrically connected with the display screen 32; the surface of the bottom plate 12 is set with a concave groove 122, and after the soft belt 31 and the display screen 32 are embedded into the concave groove 122, the soft belt 31 and the display screen 32 are in the same plane as the bottom plate 12. The soft belt 31 and the display screen 32 are fixed to the concave groove 122 of the bottom plate 12 by adopting a mode of sticking.

In the embodiment I, in order to be convenient for the soft belt 31 to extend and contract, there is also a preferred implementation in combination with the embodiment of the present disclosure. Specifically, as shown in FIG. 6, a soft belt reinforcement film is stuck on the back surface of the soft belt 31 for enhancing the hardness of the soft belt 31, and a PC film is selected as the soft belt reinforcement film.

In the embodiment I, in order to be convenient for the soft belt 31 to extend and contract, there is also a preferred implementation in combination with the embodiment of the present disclosure. Specifically, as shown in FIG. 7, the device further comprises a guide plate 4 which is fixed to the inwall of the case; the soft belt 31 is accommodated in a gap between the guide plate 4 and the inwall of the case, and is electrically connected with a back plate of the case; and the guide plate 4 is convenient for the soft belt 31 to extend and contract.

The mode of fixing the guide plate 4 and the inwall of the case are connected and fixed by sticking or screwing, and the screw fixing mode is selected in the embodiment I. The guide plate 4 forms a space for accommodating the soft belt 31 after being fixed to the inwall of the case, and the soft belt 31 extends and contracts along the direction of the guide plate 4.

### Embodiment II

The embodiment II provides a use method regarding the limit display device in the embodiment I. For the convenience of description, the limit display device is fixed to the inwall of the case. As shown in FIG. 2, after the limit rod 21 is embedded into the limit slot 11, it is set as the starting position of the limit display device that the place where the limit rod 21 locates when it is at the end point of one end of the first groove 111 which is not connected with the second groove 112. At the starting position, the body of the limit display device is hidden inside the case, and only a small part of the panel 13 of the movable assembly 1 is exposed out of the case as a handle.

When an operator needs to check the display data of the limit display device, the panel 13 of the movable assembly 1 needs to be drawn out only for a first time, and the limit rod 21 slides into the second groove 112 from the first groove 111 and is locked in the second groove 112.

After the limit rod 21 is in the locked state, if the operator no longer needs to check the display data of the limit display device, the panel 13 of the movable assembly 1 only needs to be drawn for a second time, and under the action of the reverse drawing of the elastic member 24, the limit rod 21 falls into the third groove 113 along the second groove 112, and falls into the middle of the first groove 111 after ascending along the third groove 113 and then slides to the starting position. As a result, the limit rod 21 is released from the locked state, and the limit display device is re-hidden in the case.

As shown in FIG. 3, the first edgefold 1121, the second edgefold 114, and the third edgefold 1122 locate on the left side of the second groove 112, and the fourth edgefold 1124 and the fifth edgefold 1125 locate on the right side of the second groove 113.

It is set as the starting position that the place where the limit rod 21 locates when it is at the end point of one end of the first groove 111 which is not connected with the second groove 112. After the panel 13 of the movable assembly 1 is drawn rightwards once at the starting position, the limit slot 11 is synchronously drawn rightwards. The limit rod 21 firstly slides into the first concave point 1126 along the first edgefold 1121 on the left side of the second groove 112, and the limit slot 11 stops sliding under the drawing action outside of the case. At this moment, if the movable assembly 1 is stopped drawing, the limit slot 11 slides leftwards under the stretching action of the elastic member 24. Therefore, the limit rod 21 slides out of the first concave point 1126, and after passing through the first convex point 1127, the limit rod 21 falls into the second concave point 1128. At this moment, the elastic member 24 could not draw the limit slot 11 leftwards again, and the limit rod 21 and the movable assembly 1 are in a locked state.

If the limit rod 21 slides along the fourth edgefold 1124 in the second concave point 1128 and falls into the third groove 113, the limit rod 21 falls into the second concave point 1128. After the limit rod 21 and the movable assembly 1 are in a locked state, the panel 13 of the movable assembly 1 is drawn secondly to the right on the outside of the case, the limit slot 11 slides to the right, and the limit rod 21 slides downwards from the second concave point 1128 and falls into the third groove 113. Then, the limit rod 21 is restored to the starting position.

The use method regarding the limit display device provided in the embodiment II can break through the limit of the width and the space occupied by the display screen and installation, and the valuable space of the panel occupied by the width of the display screen is practically reduced, which is simple to operate and easy to read data and is worth promoting.

It is easy for those skilled in the art to understand that the foregoing embodiments are merely preferred embodiments of the present disclosure, and are not intended to limit the present disclosure, any modifications, equivalent replacements, improvements, etc. made within the spirit and principles of the present disclosure shall be included within the scope of protection of present disclosure.

1. A limit display device, wherein the device comprises a movable assembly, a limit assembly, and a display assembly,
wherein the display assembly is fixed in the movable assembly, and the movable assembly is slidably matched with the limit assembly;
the movable assembly comprises a limit slot, the limit assembly comprises a limit rod, one end of which is embedded into the limit slot, and the other end of which is fixed to the limit assembly; and
when the movable assembly drives the display assembly to slide, the limit rod synchronously slides along a path preset by the limit slot, so as to keep a locked state or an unlocked state of the display device.

2. The limit display device of claim 1, wherein the limit slot comprises a first groove, a second groove, and a third groove,
wherein two ends of the third groove are respectively connected with the first groove and the second groove, and one end of the third groove is connected with a preset position in the middle of the first groove;
wherein when the third groove is connected with the second groove, an end face of the third groove is lower than an end face of the second groove;
wherein when the third groove is connected with the first groove, the end face of the third groove is higher than an end face of the first groove;
wherein the limit rod is embedded into the second groove after ascending along the first groove from an end point of one end of the first groove which is not connected with the second groove, and the movable assembly is in the locked state;
wherein the limit rod falls into the third groove along the second groove, and falls into the middle of the first groove after ascending along the third groove and then slides to the end point of one end of the first groove which is not connected with the second groove, and then the movable assembly completes a reset.

3. The limit display device of claim 2, wherein the second groove comprises a first edgefold, a second edgefold, a third edgefold, a fourth edgefold, and a fifth edgefold,
wherein the first edgefold, the second edgefold and the third edgefold on one hand, and the fourth edgefold and the fifth edgefold on the other hand are located on two sides of the second groove, respectively;
wherein the second edgefold forms a first concave point and a first convex point with the first edgefold and the third edgefold, respectively, and the fourth edgefold and the fifth edgefold form a second concave point;
wherein the limit rod slides into the second concave point along the first concave point and the first convex point, and the limit rod is in a locked state;
wherein if the limit rod slides into the third groove along the fourth edgefold in the second concave point, the limit rod is unlocked.

4. The limit display device of claim 3, wherein the movable assembly comprises a bottom plate and a panel, wherein the bottom plate is set with an area for accommodating the display assembly, and the panel is set with a window, the display assembly being fixed between the bottom plate and the panel, and the window being used for displaying display content and/or being electrically connected with the outside.

5. The limit display device of claim 4, wherein the limit assembly further comprises a first limit member and a second limit member,
wherein the first limit member and the second limit member respectively sleeve the bottom plate and the panel of the movable assembly, the central axes of the first limit member and of the second limit member are located on a same connecting line;
wherein the first limit member and the second limit member are respectively fixed to an inwall of the case;
wherein the movable assembly slides in a space formed by the first limit member, the second limit member and the inwall of the case.

6. The limit display device of claim 5, wherein the limit assembly further comprises an elastic member, one end of which is fixed to a fixing column set on the bottom plate, the other end of which is fixed to an inside of the case, the elastic member being kept in a stretched state, and when the limit rod is in the locked state, the elastic member can drive the limit slot to slide so that the limit rod is unlocked.

7. The limit display device of claim 5, wherein the first limit member comprises a first flange, a second flange, and a guidepost,
wherein the first flange and the second flange are respectively set on two sides of the first limit member, and meanwhile, the first flange and the second flange sleeve the bottom plate, the first flange and the second flange being respectively fixed to the inwall of the case;
the bottom plate and the panel are set with a guide sliding groove at a same position which penetrates through the bottom plate and the panel and into which the guidepost is embedded, and when the bottom plate and the panel slide, the guidepost is driven to synchronously slide along the guide sliding groove.

8. The limit display device of claim 4, wherein the display assembly comprises a soft belt and a display screen, both of which are electrically connected with each other, the surface of the bottom plate being set with a concave groove, and after the soft belt and the display screen are embedded into the concave groove, the soft belt and the display screen are in a same plane as the bottom plate.

9. The limit display device of claim 8, wherein a soft belt reinforcement film is stuck on a back surface of the soft belt for enhancing hardness of the soft belt, and a PC film is selected as the soft belt reinforcement film.

10. The limit display device of claim 9, wherein the device further comprises a guide plate which is fixed to the inwall of the case, and the soft belt is accommodated in a gap between the guide plate and the inwall of the case, the soft belt being electrically connected with a back plate of the case, and the guide plate facilitating the soft belt to extend and contract.
